(19) United States
(12) Patent Application Publication
(10) Pub. No.: US 2016/0305014 A1
(43) Pub. Date: Oct. 20, 2016

(54) PROCESS FOR COATING A CYLINDER OF AN INTERNAL COMBUSTION ENGINE AND ENGINE CYLINDER/LINER

(71) Applicants: MAHLE METAL LEVE S/A, Jundiaí (BR); MAHLE INTERNATIONAL GMBH, Stuttgart (DE)

(72) Inventors: Paulo Jose Da Rocha Mordente, Jundiaí (BR); Edney Deschauer Rejowski, Jundiaí (BR); Jose Valentim Lima Sarabanda, Sao Paulo (BR); Robert Richard Field, Sao Paulo (BR)

(21) Appl. No.: 15/101,925

(22) PCT Filed: Dec. 1, 2014
(86) PCT No.: PCT/EP2014/076083

§ 371 Date: Jun. 5, 2016

(30) Foreign Application Priority Data
Dec. 6, 2013 (BR) 10 2013 031497.8

(51) Int. Cl. C23C 16/04; C23C 16/50; F02F 1/20; C23C 16/26

(52) U.S. Cl. CPC C23C 16/045; C23C 16/26; C23C 16/50; F02F 1/20

(57) ABSTRACT

A process for coating a cylinder or a liner of an internal combustion engine may involve a plasma assisted chemical vapour deposition (PACVD) technique. The process may include placing a component to be coated in a PACVD system; forming a negative pressure within the system in an inert atmosphere including argon, hydrogen, or a mixture thereof; activating a surface of the component at a bias voltage of 300 to 550 V_{bias}; performing an ionization of the component at a bias voltage of 800 to 1200 V_{bias}; depositing an adhesive layer having a precursor element on the surface of the component; depositing a transition layer having a gradient content of increasing amorphous carbon and decreasing precursor element; and depositing an upper layer composed of an amorphous carbon with the precursor element.

### CROSS-REFERENCE TO RELATED APPLICATIONS

This application claims priority to Brazilian Patent Application No. 10 2013 031497 8, filed Dec. 6, 2013, and International Patent Application No. PCT/EP2014/076083, filed Dec. 1, 2014, both of which are hereby incorporated by reference in their entirety.

### TECHNICAL FIELD

The present invention relates, in a general manner, to an internal combustion engine and, more specifically, the invention is related to a process for coating a cylinder of an internal combustion engine or a removable liner of an internal combustion engine.

### BACKGROUND

Internal combustion engines, such as engines which employ the known Otto or Diesel cycles, are widely and commonly utilized in vehicles destined for the movement of both persons and goods, such as passenger, haulage and freight vehicles, including lorries and locomotives. In summary, these engines utilize a fuel having a high hydrocarbon content, such as fossil fuels or those originating from renewable sources, to transform the thermal energy from the burning of the fuel into kinetic energy.

There exists today growing concern in terms of a reduction in the emissions produced by internal combustion engines, which are responsible for a large part of the production of CO₂ in the atmosphere. Climate change is one of today's most relevant environmental challenges, possibly having grave consequences. This problem is being caused by the intensification of the greenhouse effect which, in turn, is related to the increase of the concentration in the atmosphere of greenhouse gases (GGs), among them carbon dioxide.

In recent years, with the objective of minimizing the emission to the environment of harmful gases, such as carbon monoxide (CO), hydrocarbon gases (HCs), or nitrogen oxides (NOx), and of particulate materials and/or other GGs, a series of technologies has been incorporated into internal combustion engines. The reduction in emissions of gases is related, among other factors, to the increase in the thermal performance of engines and, consequently, the reduction in the specific consumption of fuel.

In this sense, technologies such as electronic injection, the catalyst, particulate matter filters are, today, widespread and employed in an almost obligatory manner in all internal combustion engines. Other more recent technologies, such as direct fuel injection, the common rail for engines utilizing the Diesel cycle, and the utilization on a broader scale of technologies which have been known for a long time, such as mechanical compressors or turbocompressors, are also becoming associated with the objective of increasing energy efficiency and complying with increasingly strict emission regulations.

As a consequence, combustion engines are developing greater power per volume of displacement of the piston in the cylinder, commonly denoted as the specific power output. The performance of an Otto cycle combustion engine in the 1980s attained, on average, 50 CV/l, whereas today it may easily attain in excess of 100 CV/l. This means that the combustion pressure in the interior of the cylinders has increased considerably, also signifying that combustion engines are working under greater mechanical stresses, with faster rotation and higher temperatures. In this manner the components thereof must similarly be dimensioned to support these harsher operating conditions in order both to ensure the reliability of the assembly and to maintain the working life expected, today estimated as being approximately 300 000 km for Otto cycle engines in motorcars.

Additionally, the technology commonly known as start/stop is becoming increasingly widespread, wherein a combustion engine is automatically shut down when the vehicle is not in movement and restarted when the driver actuates the clutch or releases the brake pedal, for example. This technique has the objective of reducing the consumption of fuel and, consequently, reducing the emission of gases when the vehicle is not in movement such as, for example, when stopped at traffic lights or in a traffic jam. Nevertheless, the constant shutting down and restarting of a combustion engine signifies that components are subjected to a low degree of lubrication more frequently, in this manner increasing the wear of the components thereof.

Consequently, internal combustion engines are being subjected, increasingly, to harsher operating conditions, both in the sense of the increase in mechanical stresses, rotation and temperature, as in the sense of the reduction in lubrication.

One of the components which is most subject to the stresses generated by combustion engines is the cylinder or the piston liner, the latter in the case of engine blocks which employ removable liners. It is evident that the increase in specific power output signifies, equally, greater pressure exerted on the wall of the cylinder or of the liner. Consequently they must support both the greater stresses of pressure and of friction.

Coatings are known, realized with carbon of the diamond type (diamond like carbon, DLC) which, in summary, consists of an amorphous carbon material, and they may be realized in different forms and have properties similar to diamond with, however, advantages such as the possibility of deposition over large areas and high adherence to metal materials.

Such coatings realized in DLC present innumerable advantages in relation to greater hardness, and consequently greater wear resistance, and less friction. Nevertheless, with the conventional processes known, there are problems relating to the perfect adhesion of the coating to the substrate, which fact may mean that the coating becomes detached when subjected to high working pressures. In addition, the levels of deposition are relatively low, compromising productivity and cost in relation to manufacture.

The present invention has the objective of providing a process for coating a cylinder, overcoming the drawbacks encountered in the state of the art.

### SUMMARY

Consequently, a first objective of the present invention is to provide a process for coating a cylinder, particularly a coating of DLC, offering greater adhesion between the coating and the substrate.

A further objective of the present invention is to provide a process for coating a cylinder, particularly a DLC coating, having higher levels of deposition in relation to the processes known.

In order to satisfy the foregoing objectives, inter alia, the present invention relates to a process for coating a cylinder of an internal combustion engine, the coating being realized by plasma assisted chemical vapour deposition, wherein the process comprises the stages of:

a) provision of a component in a deposition system;
b) generation of a negative pressure within the deposition system comprised between 400 and 600 mTorr (0.53 and 0.8 millibars) in an inert atmosphere formed by argon, hydrogen or mixtures thereof;
c) activation of the surface to be deposited at a bias voltage comprised between 300 and 550 V_{bias};
d) ionization of the component at a bias voltage comprised between 800 and 1200 V_{bias} in the presence of argon, nitrogen, a hydrocarbon gas or mixtures thereof at a pressure comprised between 100 and 300 mTorr (0.13 and 0.4 millibars);
e) deposition of an adhesive layer utilizing Si as precursor, at a bias voltage comprised between 50 and 400 V_{bias} and at a pressure comprised between 200 and 500 mTorr (0.27 and 0.67 millibars) in an atmosphere formed by a hydrocarbon gas;
f) deposition of a transition layer wherein there is gradually introduced an amorphous carbon and the precursor Si is reduced, gradually, until the complete elimination of the precursor; and
g) deposition of an upper layer comprising an amorphous carbon and no precursor.

According to additional or alternative embodiments of the present invention, the following characteristics, alone or in combination, may also be present:

said cylinder is formed directly in a block of an internal combustion engine;

said cylinder is formed in a removable piston liner of a block of an internal combustion engine;

said cylinder is realized in a metal material;

said metal material is aluminium, or an aluminium alloy, or a cast iron or a steel;

the atmosphere in step (d) comprises argon and nitrogen in different proportions;

the atmosphere in step (d) comprises argon and a hydrocarbon gas in different proportions;

the hydrocarbon gas is CH₂ and/or CH₄ and/or C₂H₂ and/or CH₃SiCl₃ and/or C₄H₁₄OSi₂;

the rate of deposition is equal to or exceeds 1 μm per minute.

### DETAILED DESCRIPTION

The present invention is now described in relation to its particular embodiments. Specific embodiments are described in detail on the understanding that they shall be considered to be an exemplification of the principles thereof and not destined to limit the invention solely to that described in the present memorandum. It shall be recognized that the different teachings of the embodiments taught below may be employed separately or in any appropriate combination to produce the same technical effects.

As aforementioned, the present invention has the objective of providing a cylinder or piston liner having improved wear resistance and, equally, of offering less friction between the piston and rings and walls of the cylinder or liner.

The deposition of a layer of DLC may be realized by means of diverse techniques wherein, for the process of the invention, there is particularly of interest deposition by plasma assisted chemical vapour deposition (PACVD) generated by the hollow cathode effect (HCE). In PACVD processes, a plasma assists in the deposition of the layer in the gaseous phase. Precursors containing the elements of the layer to be deposited are utilized in the form of gases or vapours. These precursors may be, inter alia, C, Si or N, associated with an inert gas or not, depending on the layer to be deposited.

The process is initiated by placing the component in the deposition system, this component being, in particular, a cylinder of an internal combustion engine, whether this cylinder be formed directly in the engine block or formed by a piston liner. The deposition system may be any PACVD deposition system having the hollow cathode effect, that is to say with the component functioning as a cathode with the connection of an anode to each of the extremities of the component.

Subsequently, the formation of a vacuum is initiated in the interior of the deposition system in the presence of an inert atmosphere at low pressure, typically comprised between 400 and 600 mTorr. Such inert atmosphere may be formed by argon, hydrogen or a mixture thereof. This stage of vacuum generation under an inert atmosphere within the deposition system may last between 120 and 300 s, depending on the size of the component and the efficiency of the vacuum pump.

Subsequently, the sequence of the deposition process is initiated with the activation of the surface to be deposited under the inert atmosphere for a period of 180 to 360 seconds, wherein the bias voltage (V_{bias}) is raised to a value comprised between 300 and 550 V_{bias}. This stage of the activation of the surface results in an electron bombardment of the surface of the component and, in this manner, the heating of the component, permitting surface cleaning for the purpose of receiving the deposition of the layer.

Subsequently, the ionization of the component is initiated in order to receive an adhesive layer to promote good adherence of the layer of DLC on the substrate. In this respect, the ionization stage involves increasing the bias voltage from 800 to 1200 V_{bias} in the presence of an inert gas such as argon, nitrogen, or a hydrocarbon gas, such as CH₂ and/or CH₄ and/or C2H₂ and/or CH₃SiCl₃ and/or C₄H₁₄OSi₂, or mixtures thereof, similarly at a low pressure comprised between 100 and 300 mTorr. In a preferential manner, the inert atmosphere must comprise a mixture of argon with nitrogen or a mixture of argon with a hydrocarbon gas in different portions, and this stage may last from 60 to 180 seconds, depending on the thickness to be coated, preferentially utilizing Si as precursor.

Subsequently, the deposition of the adhesive layer is continued. In this stage, the bias voltage must be reduced to a value between 50 and 400 V_{bias} and the pressure reduced to 200 to 500 mTorr in an atmosphere formed, preferentially, by a hydrocarbon gas, having Si as precursor. Typically, this stage may last from 60 to 240 seconds depending on the desired coating thickness.

With the objective of ensuring good adhesion between the surface layer and the support layer, a transition layer must be provided consisting of a gradient layer wherein the quantity of the precursor, in this case Si, is gradually reduced and the quantity of C is increased in the orthogonal direction to the substrate. In this sense, as the transition layer is deposited there is a continual reduction in the percentage of the precursor and an increase in the percentage of DLC, to arrive at the third layer formed, essentially, solely by the deposition of DLC, as shall be rendered clearer below. In this manner, in this stage of deposition of the transition layer, the bias voltage must be maintained at between 50 and 400 V_{bias} in an inert atmosphere formed essentially by a hydrocarbon gas at a pressure of between 200 and 500 mTorr for 60 to 300 seconds, depending on the desired thickness of the transition layer to be obtained. Having completed the formation of the transition layer, the formation of the upper layer is initiated, realized essentially of DLC, under the same conditions of pressure, bias voltage and atmosphere to which they were subject in the stage of formation of the transition layer, for a period which may vary between 120 and 600 s, depending on the thickness of the deposition of the layer of DLC.

A coating obtained such as herein described is known, for example, in the publication WO 2012/106791, property of the applicant, incorporated herein by reference, which may have a total thickness varying between 1 and 25 μm. In spite of the layer obtained by the process of the present invention being technically similar to that described in the publication of the state of the art, the process of the present invention offers advantages on providing a better rate of deposition, permitting that it be realized more quickly, in addition to the greater adherence of the layer of DLC to the substrate such that this does not “flake” or become loosened when subjected to mechanical forces, that is to say, it permits a coating having improved tribological characteristics.

The substrate must be a metal substrate which may be formed of cast iron, a steel, aluminium or an aluminium alloy. The surface layer of DLC thus formed offers innumerable advantages, such as the low coefficient of friction, high wear resistance, high hardness and excellent adherence to the metal substrate.

In spite of the invention having been described in relation to the particular embodiments thereof, specialists in the art will be able to realize alterations or combinations not contemplated above without, nevertheless, deviating from the teachings herein described, in addition to expanding to other applications not contemplated in the present descriptive memorandum. Consequently, the appended claims shall be interpreted as covering each and every equivalent falling within the principles of the invention.

1. A process for coating a cylinder of an internal combustion engine via plasma assisted chemical vapour deposition, comprising the stages of:
a) placing a component in a deposition system;
b) forming a negative pressure within the deposition system of between 400 and 600 mTorr in an inert atmosphere composed of argon, hydrogen or a mixture thereof;
c) activating a surface of the component to be deposited at a bias voltage of between 300 and 550 V_{bias};
d) performing an ionization of the component at a bias voltage of between 800 and 1200 V_{bias} in the presence of an atmosphere including argon, nitrogen, a hydrocarbon gas or mixtures thereof at a pressure of between 100 and 300 mTorr;
e) depositing an adhesive layer having a precursor of Si at a bias voltage of between 50 and 400 V_{bias} and at a pressure of between 200 and 500 mTorr in an atmosphere composed of a hydrocarbon gas;
f) depositing a transition layer having a gradient via gradually increasing an amorphous carbon content and gradually reducing a content of the precursor of Si until the content of the precursor of Si is substantially eliminated; and
g) depositing an upper layer composed of an amorphous carbon without the precursor of Si.

2. The process according to claim 1, wherein the component is a cylinder formed directly in a block of an internal combustion engine.

3. The process according to claim 1, wherein the component is a cylinder formed in a removable piston liner of a block of an internal combustion engine.

4. The process according to claim 1, wherein the component is a metal material.

5. The process according to claim 4, wherein the metal material is aluminium, an aluminium alloy, a cast iron or a steel.

6. The process according to claim 1, wherein the atmosphere in the stage (d) includes argon and nitrogen in different proportions.

7. The process according to claim 1, wherein the atmosphere in the stage (d) includes argon and the hydrocarbon gas in different proportions.

8. The process according to claim 1, wherein the hydrocarbon gas includes one or more of CH₂, CH₄, C₂H₂, CH₃SiCl₃, and C₄H₁₄OSi₂.

9. The process according to claim 1, wherein at least one of the stage (e), the stage (f), and the stage (g) is performed at a rate of deposition equal to or exceeding 1 μm per minute.

10. A method of producing an engine cylinder or liner, comprising:
providing a plasma assisted chemical vapour deposition (PACVD) system;
placing a component in the PACVD system to be coating via a PACVD process;
forming a vacuum within the PACVD system at a pressure of 400 to 600 mTorr and in an inert atmosphere containing argon, hydrogen, or a mixture thereof;
applying a bias voltage to a surface of the component to be coated, the bias voltage ranging from 300 to 550 V_{bias};
performing an ionization of the component at a bias voltage of 800 to 1200 V_{bias} in an atmosphere containing argon, nitrogen, a hydrocarbon gas or a mixture thereof and at a pressure of 100 to 300 mTorr;
disposing an adhesive layer having a precursor element on the surface of the component at a bias voltage of 50 to 400 V_{bias} and at a pressure of 200 to 500 mTorr in an atmosphere containing a hydrocarbon gas, wherein the precursor element includes at least one of Si, C and N;
forming a transition layer on the adhesive layer, wherein the transition layer has a gradient of an increasing percentage of amorphous carbon and a decreasing percentage of the precursor element until the percentage of amorphous carbon is 100%; and
depositing a surface layer on the transition layer, the surface layer containing an amorphous carbon without the precursor element.

11. The method according to claim 10, wherein forming the transition layer includes applying a bias voltage of 50 to 400 V_{bias} in an inert atmosphere composed of a hydrocarbon gas at a pressure of 200 to 500 mTorr.

12. The method according to claim 10, wherein placing the component in the PACVD system includes placing a cylinder in an engine block.

13. The method according to claim 10, wherein placing the component in the PACVD system includes placing a cylinder in a removable piston liner of an engine block.

14. The method according to claim 10, wherein applying the bias voltage is performed in an inert atmosphere containing argon, hydrogen, or a mixture thereof.

15. The method according to claim 10, wherein the hydrocarbon gas includes at least one of CH₂, CH₄, C₂H₂, CH₃SiCl₃, and C₄H₁₄OSi₂.

16. The method according to claim 10, wherein the precursor element is Si.

17. The method according to claim 10, wherein the component is a metal material disposed in an engine block of an internal combustion engine.

18. The process according to claim 1, wherein depositing the upper layer is performed at a rate of deposition equal to or exceeding 1 μm per minute.

19. The process according to claim 1, wherein depositing the transition layer includes applying a bias voltage of 50 to 400 V_{bias} in an inert atmosphere composed of a hydrocarbon gas at a pressure of 200 to 500 mTorr.

20. A process for coating a cylinder of an internal combustion engine, comprising:
providing a plasma assisted chemical vapour deposition (PACVD) system;
placing a component in the PACVD system to be coating via a PACVD process;
forming a vacuum within the PACVD system at a pressure of 400 to 600 mTorr and in an inert atmosphere containing argon, hydrogen, or a mixture thereof;
applying a bias voltage to a surface of the component to be coated, the bias voltage ranging from 300 to 550 V_{bias};
forming an adhesive layer on the surface of the component, wherein forming the adhesive layer includes performing an ionization of the component at a bias voltage of 800 to 1200 V_{bias} for a duration in an atmosphere containing argon, nitrogen, a hydrocarbon gas or a mixture thereof and at a pressure of 100 to 300 mTorr, and after the duration reducing the bias voltage to 50 to 400 V_{bias} at a pressure of 200 to 500 mTorr in an atmosphere composed of a hydrocarbon gas and a precursor of Si;
disposing a transition layer on the adhesive layer, the transition layer including a gradient of an increasing percentage of amorphous carbon and a decreasing percentage of the precursor of Si until the transition layer has a portion substantially free of the precursor of Si; and
depositing a surface layer on the transition layer, the surface layer composed of an amorphous carbon without the precursor of Si.
